(19) United States
(12) Patent Application Publication
(10) Pub. No.: US 2026/0173927 A1
(43) Pub. Date: Jun. 18, 2026

(54) SUBSTRATES WITH INTERNAL PLATING HUBS, AND ASSOCIATED SEMICONDUCTOR DEVICE ASSEMBLIES AND METHODS OF MAKING AND USING THE SAME

(71) Applicant: Micron Technology, Inc., Boise, ID (US)

(72) Inventors: Kelvin Tan Aik Boo, Singapore (SG); Seng Kim Ye, Singapore (SG); Hong Wan Ng, Singapore (SG); Chin Hui Chong, Singapore (SG)

(21) Appl. No.: 19/379,763

(22) Filed: Nov. 5, 2025

Related U.S. Application Data
(60) Provisional application No. 63/734,746, filed on Dec. 16, 2024.

(51) Int. Cl. H10W 70/65; H10W 70/05; H10W 70/685; H10W 90/00; H10W 74/15

(52) U.S. Cl. CPC H10W 70/65; H10W 70/05; H10W 70/685; H10W 90/701; H10W 74/15; H10W 90/724; H10W 90/734

(57) ABSTRACT

Substrates with internal plating hubs (and associated systems, devices, and methods) are disclosed herein. In one embodiment, a substrate includes a dielectric material and a plated electrical network formed within the dielectric material. The plated electrical network can include an internal plating hub (a) embedded at least partially within the dielectric material, and (b) spanning multiple layers of the substrate positioned between a first side and a second side of the substrate. The plated electrical network can also include a plurality of plating lines. One or more separators can be positioned between one or more plating lines of the plurality of plating lines and the internal plating hub. The internal plating hub can include one or more ground planes. The one or more separators can include an insulating material extending from the first side or the second side of the substrate, and at least partway through the substrate.

### CROSS-REFERENCE TO RELATED APPLICATION(S)

The present application claims priority to U.S. Provisional Patent Application No. 63/734,746, filed December 16, 2024, the disclosure of which is incorporated herein by reference in its entirety.

### TECHNICAL FIELD

The present disclosure generally relates to semiconductor device assemblies, and more particularly relates to semiconductor packaging.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are "packaged" to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic partial plan view of a substrate configured in accordance with various embodiments of the present technology.

FIG. 2 is a simplified schematic cross-sectional side view of a substrate configured in accordance with various embodiments of the present technology.

FIG. 3 is a simplified schematic perspective view of a substrate configured in accordance with various embodiments of the present technology.

FIGS. 4A-4C are simplified schematic partial plan views of a substrate configured in accordance with various embodiments of the present technology at various stages of manufacturing.

FIGS. 5A-5C are simplified schematic cross-sectional side views of a substrate configured in accordance with various embodiments of the present technology at the various stages of manufacturing shown in FIGS. 4A-4C, respectively.

FIG. 6 is a simplified schematic cross-sectional side view of a semiconductor device assembly configured in accordance with various embodiments of the present technology.

FIG. 7 is a simplified schematic cross-sectional side view of another semiconductor device assembly configured in accordance with various embodiments of the present technology.

FIG. 8 is a simplified schematic cross-sectional side view of still another semiconductor device assembly configured in accordance with various embodiments of the present technology.

FIG. 9 is a schematic view of a system that includes a semiconductor device assembly configured in accordance with various embodiments of the present technology.

FIG. 10 is a flow chart illustrating a method of making a substrate in accordance with various embodiments of the present technology.

### DETAILED DESCRIPTION

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. One difficulty that arises from such complicated assemblies is in plating interconnect structures (e.g., traces, vias, pads, planes, layers) embedded within substrates (e.g., package substrates, printed circuit boards) or other semiconductor devices of such assemblies so that power and signals can be reliably and/or efficiently communicated between and/or across them. One previous method of plating internal interconnects of a substrate requires use of plating lines that are exposed at sidewalls of the substrate after singulation. After plating, the method then includes chemically etching an edge/boundary portion of the substrate to disconnect the plating lines such that open/short testing can be performed on the substrate. Another previous method of plating internal interconnects involves chemically etching a portion of a substrate in the boundary of a top side of the substrate and/or a portion of the substrate in the boundary of a bottom side of the substrate to expose plating lines, and plating using the exposed plating lines. Both of these previous techniques, however, are associated with many disadvantages, including possible trapping of chemical etchant within the substrate, potential oxidation of interconnects and/or other layers (e.g., prepreg layers) that are exposed as a result of the etching or singulation, as well as the possibility of contamination, cracking, electrical shorts, delamination, and/or excessive chemical deposition. Furthermore, access to the interconnects even after etching can remain limited in these techniques. For example, in the second technique described above, plating after etching is limited to using plating lines of only a top layer and/or a bottom layer; use of plating lines in inner (e.g., middle, intermediate, internal) layers embedded deeper within the substrate is not possible as plating lines positioned in these layers would not be exposed after etching.

To address these drawbacks and others, the present technology is directed to substrates with internal plating hubs, and to associated methods of making and using the same. The internal plating hubs (a) can function as buses (or common nodes) to which plating lines formed in the substrates can connect, and (b) can enable plating using plating lines positioned in inner (e.g., middle, intermediate, internal) layers in addition to top and/or bottom layers of plating lines. Further, the plating arrangement of an internal plating hub with corresponding plating lines facilitates using a laser (as opposed to chemical etching) after plating to (i) remove plating layers shorting plating lines together and (ii) sever connections between the plating lines and the internal plating hub, thereby enabling open/short (O/S) tests to be conducted on the substrate. Openings created using the laser can be filled with a solder resist, molding compound, underfill material, or another suitable filler material. As a result, conductive components (e.g., interconnects, prepreg components, plating lines, internal plating busses, planes, etc.) of the final substrate that are susceptible to oxidation are not exposed to air, being covered by (a) the filler material in the openings formed by the laser and (b) at the top, bottom, and sides of the substrates with either a dielectric material or a plating layer. Therefore, the present technology is expected to offer several advantages in comparison to previous plating techniques and structures, including (i) plating using plating lines positioned in inner layers, (ii) use of a plating arrangement that facilitates easily covering materials that are susceptible to oxidation, and (iii) use of a laser (in lieu of chemical etching) to remove plating layers and sever connections (thereby reducing, minimizing, or eliminating one or more of the associated risks of (1) chemical etchants becoming trapped in the substrates, and/or (2) contamination, cracking, electrical shorts, and/or delamination).

Methods associated with the present technology include plating interconnects of a substrate using a plating arrangement that includes an internal plating hub and plating lines connected to the internal plating hub. For example, one method of the present technology can include providing (a) a substrate made of a dielectric material, and (b) a unified electrical network formed within the substrate. The unified electrical network can include a plating arrangement having (i) an internal plating hub (e.g., one or more ground planes and/or one or more vias connecting two or more ground planes), and (ii) plating lines connected to the internal plating hub. In other words, the internal plating hub can serve as a common node that electrically integrates plating lines of the unified electrical network to one another via the internal plating hub. The unified electrical network can further include other interconnects (e.g., pads, vias, traces, planes, layers, etc.) that are connected to the plating lines. The substrate can include a side having an opening formed therein that exposes a portion of the unified electrical network through the side.

In some embodiments, the method further includes (a) immersing the semiconductor assembly in a solution containing metal ions, and (b) supplying a voltage to the solution, thereby causing the metal ions to be drawn to the portion of the unified electrical network that is exposed through the opening formed in the substrate. The exposed portion of the electrical network can be a metal plane, part of the internal plating hub, part of a plating line, a trace, a via, a pad, or another part of the unified electrical network. In some embodiments, the method includes electrically plating the entire unified electrical network, such as by transferring metal ions from the exposed portion of the unified electrical network to the internal plating hub, and subsequently transferring metal ions from the internal plating hub to other portions of the unified electrical network via the plating lines and interconnects connected thereto. After the plating process, the method can include splitting the unified electrical network into electrically distinct components, such as by creating a hole (e.g., using a laser) in the substrate that severs the plating lines from the internal plating hub and removes portions of a plating layer that undesirably short plating lines together. In some embodiments, the hole can be filled with an insulating material to ensure electrical isolation of the components and to cover exposed portions of the electrical network that are susceptible to oxidation.

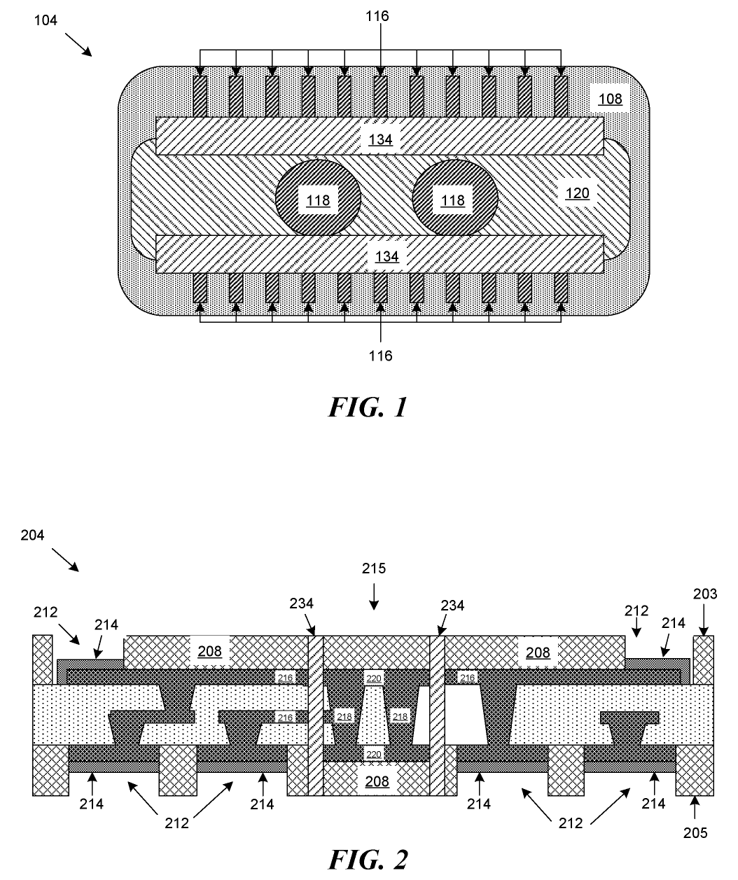

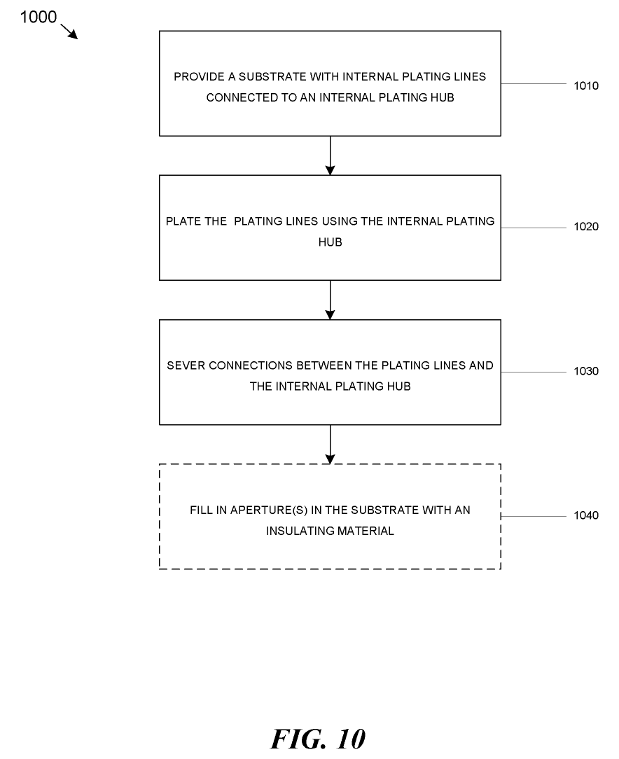

Various aspects of the present technology are described in greater detail below with reference to FIGS. 1-10. For example, FIGS. 1-8 and the associated text below describe various substrates with internal plating hubs. One or more of these substrates (including other substrates configured in accordance with the present technology) can be made from methods similar to the example method described above. Additionally, or alternatively, one or more of these substrates (including other substrates configured in accordance with the present technology) can be made using other methods of the present technology, such as the method described in greater detail below with reference to FIG. 10. Although the present technology is primarily described above and below in the context of substrates (e.g., package substrates, printed circuit boards, etc.), such as for use in or with semiconductor devices, semiconductors assemblies, semiconductor packages, etc.), the present technology is not so limited. Indeed, several aspects of the present technology can be employed in other electrical components besides substrates, such as within semiconductor devices.

FIG. 1 illustrates a substrate 104 configured in accordance with various embodiments of the present technology. As shown, the substrate 104 includes a plated electrical network formed at least partially within a dielectric material 108. The plated electrical network includes plating lines 116 (e.g., conductive traces, conductive planes) and an internal plating hub 120. The internal plating hub 120 is also referred herein as an “internal hub,” an “internal plating bus,” an “internal bus,” and the like. The internal plating hub 120 is situated (e.g., embedded) within the substrate 104. For example, the internal plating hub 120 can be fully (e.g., completely) or at least partially enclosed by (e.g., covered by, enveloped by, positioned more internal to/closer to a center of the substrate 104 than) the dielectric material 108. The internal plating hub 120 can be embodied as one or more conductive traces, conductive planes (e.g., ground planes), conductive layers (e.g., metal layers), vias, or other suitable conductive structures. As a specific example, the internal plating hub 120 can include one or more ground planes formed within the substrate 104 (e.g., within the dielectric material 108). The internal plating hub 120 can further include one or more interconnects that electrically couple components of the internal plating hub 120 to one another. Continuing with the specific example provided above, in embodiments in which the internal plating hub 120 includes two or more ground planes, the internal plating hub 120 can further include one or more interconnects that electrically couple the two or more ground planes to one another. In this vein, FIG. 1 illustrates two vias 118 (e.g., copper-filled vias) that can be used in the internal plating hub 120 to couple components (e.g., two or more ground planes) of the internal plating hub 120 to one another. Thus, the internal plating hub 120 can span across multiple layers of the substrate 104, such as multiple layers between a first side (e.g., a top side) of the substrate 104 and a second side (e.g., a bottom side) of the substrate 104.

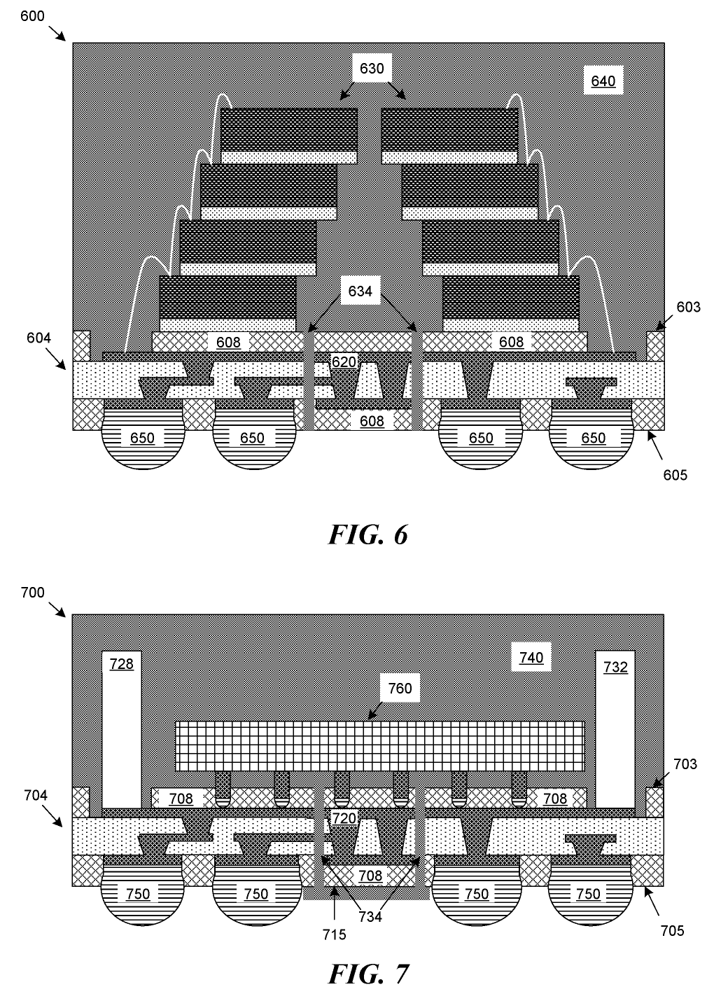

The substrate 104 can further include one or more separators 134. In some embodiments, the separators 134 can include plugs of insulating material (e.g., solder resist) that extend into the substrate 104, such as from an exterior of the substrate 104. In other embodiments, the separators 134 can include apertures devoid of a filler material, or apertures filled with a filler material (e.g., a molding compound/encapsulant, an underfill material, etc.) during assembly of a semiconductor device assembly/package (e.g., the semiconductor device assembly 600, 700, and/or 800 described in greater detail below with reference to FIGS. 6-8). Each of the separators 134 of FIG. 1 is configured to separate (e.g., electrically isolate) (i) one or more of the plating lines 116 from the internal plating hub 120 and/or (ii) two or more of the plating lines 116 from one another. In other words, the separators 134 can be used to maintain the integrity and functionality of the plated electrical network within the substrate 104 (e.g., thereby enabling open/short tests on the substrate 104). The separators 134 may also be used to cover portions of the plating lines 116, portions of the internal plating hub 120, portions of other interconnects, and/or portions of other materials/structures of the substrate 104, such as to prevent exposure to air and/or to reduce the risk of oxidation.

FIG. 2 illustrates a simplified schematic cross-sectional side view of a substrate 204 configured in accordance with various embodiments of the present technology. The substrate 204 can be an example of the substrate 104 of FIG. 1, or of other substrates configured in accordance with various embodiments of the present technology. Thus, similar reference numbers are used across FIGS. 1 and 2 to denote identical or at least generally similar components, and a detailed discussion of such components is largely omitted here for the sake of brevity in light of the detailed discussion provided above. In the illustrated embodiment, the substrate 204 includes a dielectric material 208, a plated electrical network formed within the dielectric material 208, and one or more separators 234. The substrate 204 further includes a first side 203 (e.g., a top side) and a second side 205 (e.g., a bottom side) opposite the first side 203.

The electrical network is illustrated with plating lines 216 (e.g., traces, planes, pads) and an internal plating hub 220 (e.g., planes, layers, traces, pads, vias). In the illustrated embodiment, the internal plating hub 220 is illustrated with two horizontal layers (e.g., planes, traces) that are connected to one another by two vias 218. Thus, the internal plating hub 220 can span across multiple layers of the substrate 204, such as multiple layers between the first side 203 of the substrate 204 and the second side 205 of the substrate 204. In some embodiments, the horizontal layers of the internal plating hub 220 can include ground planes.

The substrate 204 further includes one or more openings 212 (e.g., apertures, cutouts, recesses) formed therein. For example, the substrate 204 includes (a) one or more openings 212 formed in the dielectric material 208 at a first side 203 of the dielectric material 208 and (b) one or more openings 212 formed in the dielectric material 208 at the second side 205 of the dielectric material 208. In other embodiments, the substrate 204 can include one or more openings 212 formed in only the first side 203 (and not the second side 205), or one or more openings 212 formed in only the second side 205 (and not the first side 203). The opening(s) 212 on the first side 203 and/or the opening(s) 212 on the second side 205 of the substrate 204 can include a single (e.g., only one) opening, such as a single (e.g., continuous) gap, hole, slot, trench, etc. In other embodiments, the opening(s) 212 on the first side 203 and/or the opening(s) 212 on the second side 205 can include multiple openings, such as a plurality of (e.g., discrete) gaps, holes, slots, trenches, etc.

As shown, each opening 212 is positioned and sized such that one or more portions of the electrical network formed within the dielectric material 208 is/are positioned within the opening 212. For example, in the illustrated embodiment, portions of plating lines 216 are positioned within the openings 212. In the illustrated embodiment, the portions of the plating lines 216 positioned within the openings 212 are covered by a plating layer 214 (e.g., a metal coating, a metal film). More specifically, the plating layer 214 is disposed in the openings 212 and over the portions of the plating lines 216 positioned therein.

Each separator 234 of the substrate 204 can be configured to electrically isolate (a) the internal plating hub 220 from one or more of the plating lines 216 and/or (b) two or more of the plating lines 216 from one another. Additionally, or alternatively, the separators 234 can be configured to cover portions of the electrical network that would otherwise be exposed to air within the substrate 204 absent the separators 234. Thus, the separators 234 are expected to limit and/or prevent oxidation of portions of the electrical network.

In the illustrated embodiment, the separators 224 extend completely through the substrate 204 from the first side 203 to the second side 205. In other embodiments, one or more of the separators 234 can terminate at a location within the substrate 204 such that the one or more separators 234 do not extend completely through the substrate 204. For example, a separator 234 can extend from (a) the first side 203 or the second side 205 of the substrate 204 to (b) a location between the first side 203 and the second side 205 such that the separator 234 (i) electrically isolates at least one of the plating lines 216 from the internal plating hub 220, (ii) covers otherwise exposed portions of the electrical network, and/or (iii) terminates at the location without extending fully though the substrate 204. In some embodiments, the separators 234 can comprise plugs of insulating material. The insulating material can include a solder resist, a solder mask (e.g., liquid photoimageable (LPI) solder mask, dry film solder mask, epoxy liquid solder mask, ultraviolet (UV) curable solder mask, or thermal curable solder mask), a dielectric, or another suitable insulating material. In other embodiments, the separators 234 can include insulating material (e.g., a molding encapsulant, an underfill material) introduced into corresponding apertures of the substrate 204, such as during assembly of a semiconductor device assembly/package that includes the substrate 204. Additional details regarding semiconductor assemblies configured in accordance with various embodiments of the present technology are provided and discussed in detail below with reference to FIGS. 6-8.

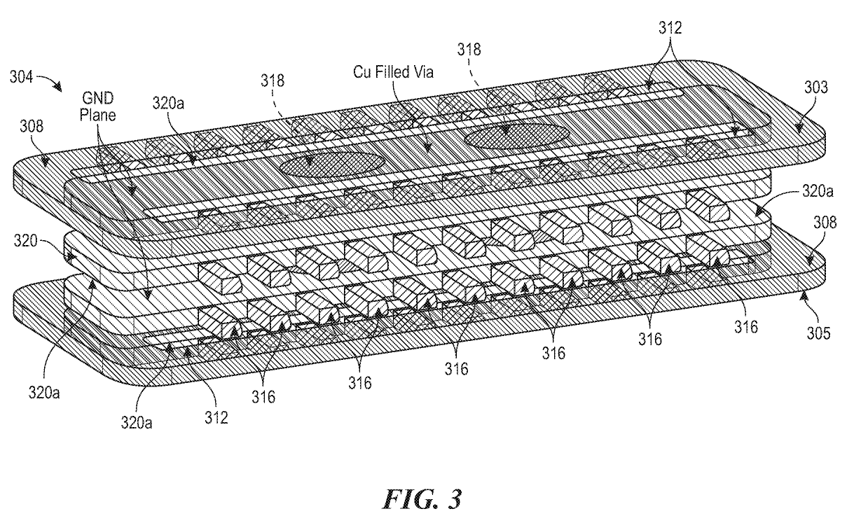

FIG. 3 is a simplified schematic perspective view of a substrate 304 configured in accordance with various embodiments of the present technology. The substrate 304 can be an example of the substrate 104 of FIG. 1, the substrate 204 of FIG. 2, or other substrates configured in accordance with various embodiments of the present technology. Thus, similar reference numbers are used across FIGS. 1-3 to denote identical or at least generally similar components, and a detailed discussion of such components is largely omitted here for the sake of brevity in light of the detailed discussion provided above with reference to FIGS. 1 and 2.

As shown, the substrate 304 includes a first side 303 and a second side 305 opposite the first side 303. The substrate 304 further includes an electrical network formed at least partially within a dielectric material 308. The electrical network includes plating lines 316 and an internal plating hub 320. The internal plating hub 320 is situated (e.g., embedded) within the substrate 304. For example, the internal plating hub 320 can be fully (e.g., completely) or at least partially enclosed by (e.g., covered by, enveloped by, positioned more internal to/closer to a center of the substrate 304 than) the dielectric material 308.

As discussed above, the internal plating hub 320 can be embodied as one or more conductive traces, conductive planes (e.g., ground planes), conductive layers (e.g., metal layers), vias, or other suitable conductive structures. The internal plating hub 320 can further include one or more interconnects that electrically couple components of the internal plating hub 320 to one another. In the specific example shown in FIG. 3, the internal plating hub 320 includes a plurality of ground planes 320a formed at least partially within the dielectric material 308, and the ground planes 320a are connected to one another using vias 318 (e.g., copper-filled vias). Each of the ground planes 320a of FIG. 3 correspond to a respective plurality of the plating lines 316. More specifically, the plurality of ground planes 320a are arranged in multiple layers within the substrate 304, and the plating lines 316 are arranged in corresponding pluralities of plating lines 316.

For example, the plurality of ground planes 320a include a first ground plane 320a positioned proximate the first side 303 of the substrate 304, and the plating lines 316 include a first plurality of plating lines 316 that correspond to the first ground plane 320a and that are similarly positioned proximate the first side 303 of the substrate 304. The plurality of ground planes 320a also include a second ground plane 320a positioned proximate the second side 305 of the substrate 304, and the plating lines 316 include a second plurality of plating lines 316 that correspond to the second ground plane 320a and that are similarly positioned proximate the second side 305 of the substrate 304. The plurality of ground planes 320a can further include one or more ground planes 320a (two shown in FIG. 3 as an example) that are positioned between (a) the first ground plane 320a proximate the first side 303 of the substrate 304 and (b) the second ground plane 320a proximate the second side 305 of the substrate 304. The one or more ground planes 320a can correspond to internal (e.g., interior, inner, intermediate, middle) layers of the substrate 304 that are positioned between the first side 303 and the second side 305. The plating lines 316 can further includes one or more pluralities of plating lines 316 that correspond to the one or more ground planes 320a and that are similarly positioned at/correspond to internal layers of the substrate 304 between the first side 303 and the second side 305.

In the illustrated embodiment, the plating lines 316 are coupled to the internal plating hub 320. Thus, the electrical network formed within the dielectric material 308 can be a unified electrical network (also referred to herein as a “unified plating arrangement,” a “plating arrangement,” and the like) in which the plating lines 316, the ground planes 320a, and the vias 318 are coupled to one another. For example, FIG. 3 can be an illustration of the substrate 304 at an intermediate stage of manufacturing, such as at a stage before connects between the plating lines 316 and the internal plating hub 320 are severed (e.g., using a laser), as discussed in greater detail below.

As shown, the substrate 304 further includes one or more openings 312 (e.g., apertures, cutouts, recesses) formed therein. For example, the substrate 304 can include one or more openings 312 formed at or proximate locations at which plating lines 316 interface with (e.g., corresponding ground planes 320a of) the internal plating hub 320. The opening(s) 312 can include gaps, holes, slots, trenches, etc. In the illustrated embodiment, each opening 312 extends from the first side 303 of the substrate 304 to the second side 305 of the substrate 304. In other embodiments, opening(s) can extend only partway into the substrate 304 and/or terminate at a midpoint location within the substrate 340. In addition, as shown in FIG. 3, each opening 312 spans across all of the plating lines 316 on a given side of the internal plating hub 320. In other embodiments, the opening(s) 312 can span across a subset representing less than all of the plating lines 316 on a given side of the internal plating hub 320.

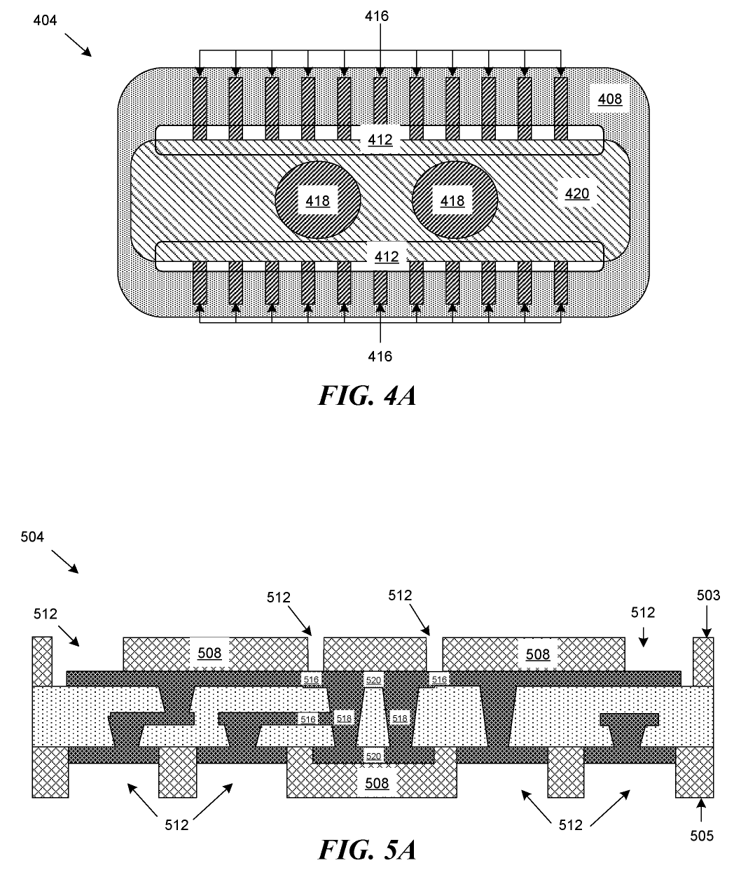

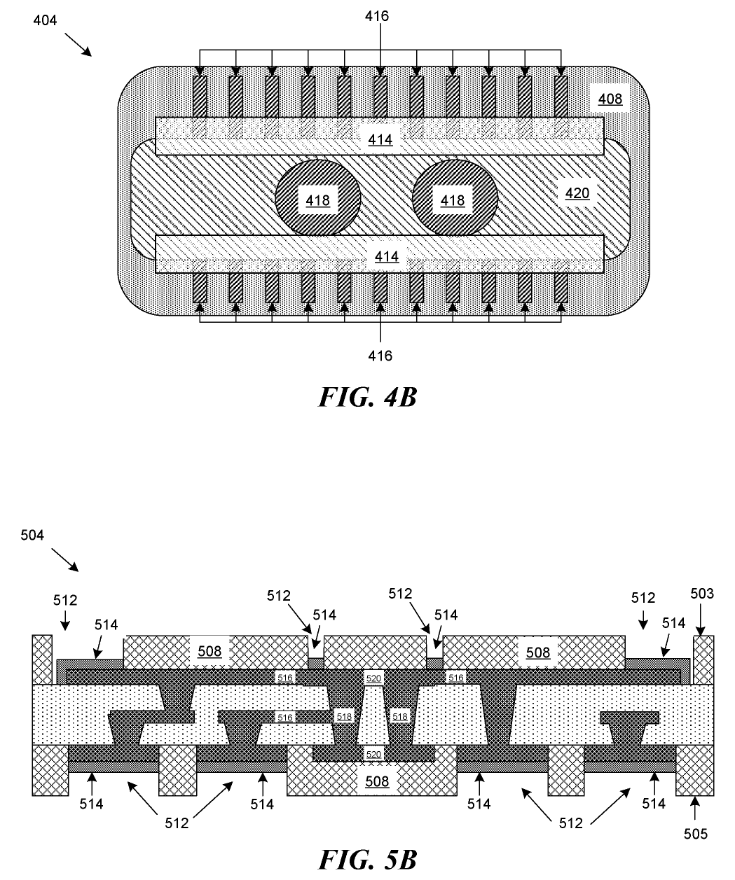

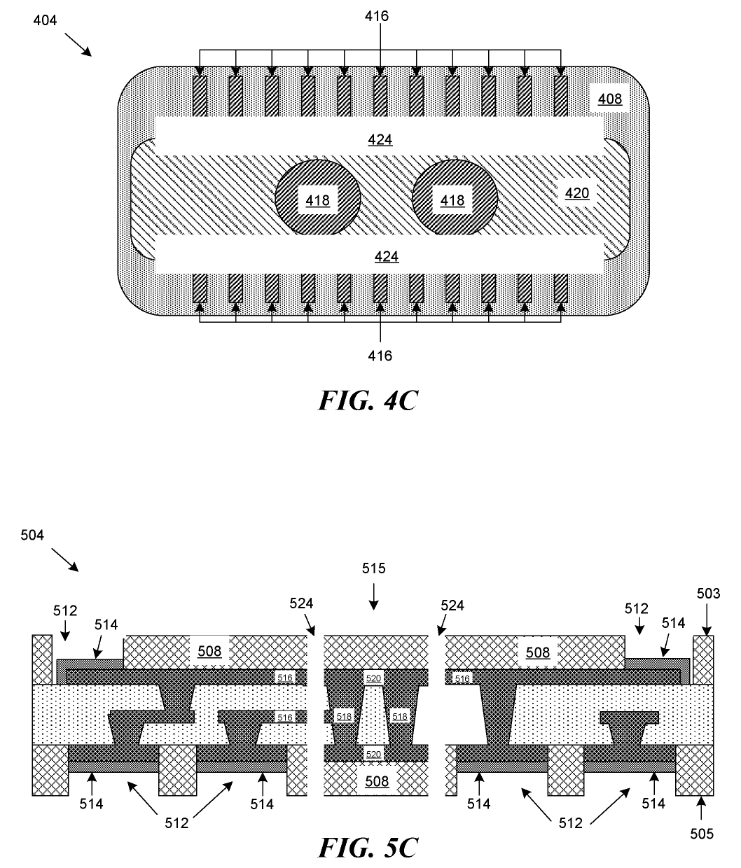

As discussed above, FIG. 3 can be an illustration of the substrate 304 at an intermediate stage of manufacturing. FIGS. 4A-5C described below are simplified schematic partial plan views illustrating a sequence of stages of manufacturing, starting from the stage of manufacturing shown in FIG. 3. For example, FIGS. 4A-4C are simplified schematic partial plan views of a substrate 404 configured in accordance with various embodiments of the present technology, and FIGS. 5A-5C are simplified schematic cross-sectional view of a substrate 504 configured in accordance with various embodiments of the present technology. FIGS. 4A-4C can illustrate a sequence of stages for manufacturing the substrate 104 of FIG. 1, and/or FIGS. 5A-5C can illustrate a sequence of stages for manufacturing the substrate 104 of FIG. 2. Additionally, or alternatively, FIGS. 4A and 5A can correspond to the stage of manufacturing shown in FIG. 3.

The substrate 404 and/or the substrate 504 can be an example of the substrate 104 of FIG. 1, the substrate 204 of FIG. 2, the substrate 304 of FIG. 3, or other substrates configured in accordance with various embodiments of the present technology. Additionally, or alternatively, the substrate 504 of FIGS. 5A-5C can be an example of the substrate 404 of FIGS. 4A-4C. Thus, similar reference numbers are used across FIGS. 1-5C to denote identical or at least generally similar components, and a detailed description of these components is largely omitted here for the sake of brevity in light of the detailed description provided above with reference to FIGS. 1-3.

Referring to FIG. 4A, the substrate 404 is at least partially formed of a dielectric material 408 having a unified electrical network formed therein. The unified electrical network (also referred to herein as a “plating arrangement,” an “embedded circuit,” and the like) includes an internal plating hub 420 (e.g., one or more ground planes, one or more vias 418, etc.) and plating lines 416 connected to the internal plating hub 420. In the illustrated embodiment, the substrate 404 is shown with openings 412 formed therein that expose one or more portions of the unified electrical network. For example, the openings 412 can expose (e.g., directly expose) portions of the plating lines 416 and/or portions of the internal plating hub 420 (e.g., one or more ground planes).

Referring now to FIG. 5A, the substrate 504 includes a first side 503 and a second side 505 opposite the first side 503. The substrate 504 is at least partially formed of a dielectric material 508 having a unified electrical network (e.g., an embedded circuit, a plating arrangement) formed therein. The unified electrical network includes an internal plating hub 520 and plating lines 516 connected to the internal plating hub 520. As a specific example, the internal plating hub 520 includes one or more ground planes and one or more vias 518 that serve as vertical interconnects between various conductive structures (e.g., multiple layers of the internal plating hub) of the electrical network.

The substrate 504 further includes openings 512 formed therein. The openings 512 are positioned and sized such that one or more portions of the unified electrical network formed within the substrate 504 are exposed within the openings 512. In the illustrated embodiment, the openings 512 are positioned and sized such that portions of the plating lines 516 are positioned and/or exposed within the openings 512.

Referring now to FIG. 4B, the substrate 404 of FIG. 4A is shown at a next stage of manufacturing. More specifically, one or more plating layers 414 are disposed atop corresponding portions of the unified electrical network formed within the substrate 404. In some embodiments, the plating layers 414 can be disposed in the openings 412 (FIG. 4A) formed in the substrate 404 and/or atop the portions of the unified electrical network that are positioned/exposed within the openings 412. In some embodiments, the plating layer(s) 414 can comprise a mask, a film, a coating, a deposition, or a metallization. In these and other embodiments, the plating layer 414 can comprise gold, silver, copper, nickel, palladium, platinum, tin, rhodium, or aluminum, or any of the foregoing elements in combination, either as an alloy or unalloyed mixture. In some embodiments, the plating layers 414 can be a portion of a mask used for plating components of the unified electrical network. In some embodiments, after disposing the plating layer(s) 414, the unified electrical network can be referred to as a plated, unified electrical network.

Referring now to FIG. 5B, the substrate 504 of FIG. 5A is shown at a next stage of manufacturing, corresponding to the stage of manufacturing of the substrate 404 illustrated in FIG. 4B. More specifically, a plating layer 514 (e.g., metal coating, metal film) can be disposed within the openings 512 and over one or more portions of the unified electrical network formed within the dielectric material 508 of the substrate 504. In some embodiments, the plating layer 514 can fully or partially cover and/or encapsulate portions of the unified electrical network (e.g., portions of the plating lines 516) that are exposed within the openings 512.

Referring now to FIG. 4C, the substrate 404 of FIG. 4B is illustrated at a next stage of manufacturing. More specifically, the substrate 404 of FIG. 4C includes one or more apertures 424 (e.g., holes, voids) formed in the substrate 404. As shown, the apertures 424 are positioned in FIG. 4C at locations along the substrate 404 corresponding generally to where the openings 412 (FIG. 4A) and the plating layers 414 (FIG. 4B) were positioned.

In some embodiments, the apertures 424 can be formed using a laser or laser drill. For example, a laser or laser drill can be used to form the apertures 424 and thereby remove the plating layers 414 of FIG. 4B (e.g., as opposed to using a chemical etchant to remove the plating layers 414). As shown, the apertures 424 can extend from an outer layer (or side) of the dielectric material 408 into and/or fully through the dielectric material 408. Additionally, or alternatively, as discussed in greater detail below with reference to FIG. 5C, the laser or laser drill can be used to sever connections between the plating lines 416 and the internal plating hub 420, thereby transforming the plated, unified electrical network into a plated electrical network (e.g., a plated embedded circuit).

As also discussed in greater detail below, the apertures 424 can be configured to separate (e.g., electrically isolate) l. In some embodiments, all or a first subset of the apertures 424 can be left unfilled. In such embodiments, all or the first subset of the unfilled apertures 424 can be referred to as “separators,” at least when configured to separate (i) the internal plating hub 420 from one or more of the plating lines 416 and/or (b) two or more of the plating lines 416 from one another. In these and other embodiments, all or a second subset of the apertures 424 can be filled with an insulative material (e.g., at a next stage of manufacturing, such as the stage shown in FIG. 1) to form separators similar to the separators 134 of FIG. 1. Indeed, the substrate 104 of FIG. 1 can be an example of the substrate 404 of FIG. 4C at a next stage of manufacturing from that shown in FIG. 4C. In such embodiments, the insulative material used to fill the apertures 424 can be configured to separate (i) the internal plating hub 420 from one or more of the plating lines 416 and/or (b) two or more of the plating lines 416 from one another. Additionally, or alternatively, the insulative material can be configured to cover portions of the plating lines 416, portions of the internal plating hub 420, portions of other interconnects, and/or portions of other materials/structures of the substrate 404, such as to prevent exposure to air and/or to reduce the risk of oxidation. As discussed above with reference to FIGS. 1 and 2, the insulator material can be a solder resist, a molding compound, an underfill material, or another suitable filler material.

Referring now to FIG. 5C, the substrate 504 of FIG. 5B is illustrated at a next stage of manufacturing, corresponding to the stage of manufacturing shown in FIG. 4C. More specifically, the substrate 504 of FIG. 5C includes one or more apertures 524 (e.g., holes, voids) formed in the substrate 504. As shown, the apertures 524 are positioned in FIG. 5C at locations along the substrate 504 corresponding generally to where the openings 512 (FIG. 5A and 5B) and the plating layers 514 (FIG. 5B) were positioned.

As discussed above, the apertures 524 can be formed using a laser or laser drill. For example, a laser or laser drill can be used to form the apertures 524 and thereby remove a portion of the plating layers 514 of FIG. 5B (e.g., as opposed to using a chemical etchant to remove the portion of the plating layers 514). Additionally, or alternatively, the laser or laser drill can be used to sever connections between the plating lines 516 and the internal plating hub 520. For example, the apertures 524 are shown as extending from the first side 503 of the substrate 504, through the dielectric material 508, to the second side 505 of the substrate 504. Continuing with this example, the laser or laser drill can be used to sever connections between (a) plating lines 516 positioned at top, middle, and/or bottom layers of the substrate 504 and (b) corresponding portions (e.g., ground planes, vias 518) of the internal plating hub 520. Thus, the apertures 524 can separate (e.g., electrically isolate) (a) the internal plating hub 520 from one or more plating lines 516, and/or (b) two or more of the plating lines 516 from one another. As a result, in some embodiments, the apertures 524 can form a central hub routing region 515 in the substrate 504 that (a) includes the internal plating hub 520, (b) is isolated from the plating lines 516 at the apertures 524, and (c) can provide routing flexibility when the substrate is incorporated into a semiconductor assembly, as described in greater detail below. In other embodiments, the apertures 524 can extend only partway into/through the substrate 504, such as from the first side 503 or from the second side 505.

Similar to the apertures 424 of FIG. 4C, all or a first subset of the apertures 524 can be left unfilled. In such embodiments, all or the first subset of the unfilled apertures 524 can be referred to as “separators,” at least when configured to separate (i) the internal plating hub 520 from one or more of the plating lines 516 and/or (b) two or more of the plating lines 516 from one another. In these and other embodiments, all or a second subset of the apertures 524 can be filled with an insulative material (e.g., at a next stage of manufacturing, such as the stage shown in FIG. 2) to form separators similar to the separators 234 of FIG. 2. Indeed, the substrate 204 of FIG. 2 can be an example of the substrate 504 of FIG. 5C at a next stage of manufacturing from that shown in FIG. 5C. In such embodiments, the insulative material used to fill the apertures 524 can be configured to separate (i) the internal plating hub 520 from one or more of the plating lines 516 and/or (b) two or more of the plating lines 516 from one another. Additionally, or alternatively, the insulative material can be configured to cover portions of the plating lines 516, portions of the internal plating hub 520, portions of other interconnects, and/or portions of other materials/structures of the substrate 404, such as to prevent exposure to air and/or to reduce the risk of oxidation. As discussed above with reference to FIGS. 1 and 2, the insulator material can be a solder resist, a molding compound, an underfill material, or another suitable filler material.

FIG. 6 is a simplified schematic cross-sectional side view of a semiconductor device assembly 600 (“the assembly 600”) configured in accordance with various embodiments of the present technology. As shown, the assembly 600 includes a substrate 604 with an internal plating hub 620. The substrate 604 can be an example of the substrate 104 of FIG. 1, the substrate 204 of FIG. 2, the substrate 304 of FIG. 3, the substrate 404 of FIGS. 4A-4C, the substrate 504 of FIGS. 5A-5C, or other substrates configured in accordance with various embodiments of the present technology. Thus, similar reference numbers are used across FIGS. 1-6 to denote identical or at least generally similar components, and a detailed discussion of such components is largely omitted here for the sake of brevity in light of the detailed discussion provided above with reference to FIGS. 1-5C.

The substrate 604 is at least partially formed of a dielectric material 608 having a plurality of interconnect structures (e.g., traces, vias, planes, plating lines, the internal plating hub 620) formed therein. The substrate 604 further includes a first side 603 and a second side 605 opposite the first side 603. The plurality of interconnect structures can extend between the first side 603 and the second side 605. In some embodiments, the substrate 604 can be a package substrate and/or a printed circuit board.

In the illustrated embodiment, the assembly 600 further includes a plurality of semiconductor devices 630 stacked on the first side 603 of the substrate 604. As a non-limiting example, the plurality of semiconductor devices 630 are arranged in two stacks on the first side 603 of the substrate 604. Continuing with this example, the semiconductor devices 630 of each stack are positioned in a cascaded arrangement such that bond pads on top surfaces of each of the semiconductor devices 630 can be connected, through the first side 603 of the substrate 604, to interconnect structures positioned within the substrate 604, using one or more cascaded wire bonds. In some embodiments, the semiconductor devices 630 include semiconductor dies (e.g., memory dies and/or logic dies). In these and other embodiments, the semiconductor devices 630 can be stacked on the first side 603 of the substrate 604 using any suitable technique, such as direct chip attach (DCA) techniques.

As shown in FIG. 6, the assembly 600 can further include a plurality of external contacts 650 formed at the second side 605 of the substrate 604. One or more of the external contacts 650 are coupled to the semiconductor devices 630 of the assembly 600 via (a) respective interconnects formed within the substrate 604 and (b) corresponding wire bonds. The external contacts 650 can include solder balls, conductive pillars, and/or other suitable conductive structures for coupling the semiconductor devices 630 of the assembly 600 to external devices and systems, such as via the one or more wire bonds and the interconnects formed within the substrate 604.

The assembly 600 further includes an encapsulant 640. The encapsulant 640 can be formed of a molding compound, such as an epoxy molding compound (EMC), a silicone molding compound, a polyurethane molding compound, a thermoplastic molding compound, or another suitable material. In the illustrated embodiment, the encapsulant 640 surrounds and encapsulates the stacked semiconductor devices 630 that are disposed atop the first side 603 of the substrate 604.

In addition, as shown in FIG. 6, the encapsulant 640 can be used to fill in apertures (e.g., the apertures 524 of FIG. 5C) formed in the substrate 604 and thereby form separators 634 within the substrate 604. For example, the substrate 604 can be provided with apertures formed within the substrate 604 that are devoid of a filler material. Continuing with this example, after the semiconductor devices 630 are stacked atop the substrate 604 and coupled to interconnects formed within the substrate 604, the encapsulant 640 can be applied over the semiconductor devices 630 such that the encapsulant 640 (a) encapsulates the semiconductor devices 630 and (b) fills in the apertures in the substrate 604 to form the separators 634. Alternatively, the substrate 604 can be provided with apertures already filled with (e.g., plugs) of insulating material that serve as separators. Continuing with this example, the semiconductor devices 630 can then be stacked atop the substrate 604, and the encapsulant 640 can be applied over the semiconductor devices 630 to cover the semiconductor devices 630.

In the illustrated embodiment, the internal plating hub 620 of the substrate 604 is not utilized by the fully assembled assembly 600. In other embodiments, the internal plating hub 620 can be used to provide routing flexibility between, for example, (i) the second side 605 and the first side 603 of the substrate 604, (ii) between a first location at the first side 603 of the substrate 604 and a second location at the first side 603 of the substrate 604, and (iii) between a first location at the second side 605 of the substrate 604 and a second location at the second side 605 of the substrate 604. One example is shown in FIG. 7 and described in detail below.

FIG. 7 is a simplified schematic cross-sectional view of another semiconductor device assembly 700 (“the assembly 700”) configured in accordance with various embodiments of the present technology. As shown, the assembly 700 includes a substrate 704 with an internal plating hub 720. The substrate 704 can be an example of the substrate 104 of FIG. 1, the substrate 204 of FIG. 2, the substrate 304 of FIG. 3, the substrate 404 of FIGS. 4A-4C, the substrate 504 of FIGS. 5A-5C, the substrate 604 of FIG. 6, or other substrates configured in accordance with various embodiments of the present technology. Thus, similar reference numbers are used across FIGS. 1-7 to denote identical or at least generally similar components, and a detailed discussion of such components is largely omitted here for the sake of brevity in light of the detailed discussion provided above with reference to FIGS. 1-6.

The substrate 704 is at least partially formed of a dielectric material 708 having a plurality of interconnect structures (e.g., traces, vias, planes, plating lines, the internal plating hub 720) formed therein. The substrate 704 further includes a first side 703 and a second side 705 opposite the first side 703. The plurality of interconnect structures can extend between the first side 703 and the second side 705. In some embodiments, the substrate 704 can be a package substrate and/or a printed circuit board.

In the illustrated embodiment, the assembly 700 further includes a semiconductor device 760, an inductor 728, and a capacitor 732 that are each stacked on the first side 703 of the substrate 704. In some embodiments, the semiconductor device 760 includes a semiconductor die (e.g., memory dies and/or logic dies). In these and other embodiments, the semiconductor device 760 can be stacked on the first side 703 of the substrate 704 using any suitable technique, such as a flip chip configuration in which bond pads of the semiconductor device 760 are coupled to bonding sites at the first side 703 of the substrate 704 (e.g., using solder balls and/or other electrical contacts).

As a non-limiting example, the semiconductor device 760 is arranged on the first side 703 of the substrate 704 such that a first set of electrical contacts couples the semiconductor device 760 to first interconnect structures of the substrate 704 shown to the left of the internal plating hub 720, a second set of electrical contacts couples the semiconductor device 760 to second interconnect structures of the substrate 704 shown to the right of the internal plating hub 720, and a third set of electrical contacts couples the semiconductor device 760 to the internal plating hub 720 of a central hub routing region 715 of the substrate 704. Continuing with this example, the first interconnect structures of the substrate 704 can couple electrical contacts of the first set to one another via the substrate 704. Additionally, or alternatively, the first interconnect structures of the substrate 704 and the first set of electrical contacts can couple the semiconductor device 760 (a) to the inductor 728 at the first side 703 of the substrate 704 and/or (b) to a corresponding external contact 750 formed at the second side 705 of the substrate 704.

Referring now to the other side of the substrate, the second interconnect structures of the substrate 704 can couple electrical contacts of the second set to one another via the substrate 704. Additionally, or alternatively, the second interconnect structures of the substrate 704 and the second set of electrical contacts can couple the semiconductor device 760 (a) to the capacitor 732 at the first side 703 of the substrate 704 and/or (b) to a corresponding external contact 750 formed at the second side 705 of the substrate 704. Referring now to the central hub routing region 715 of the substrate 704, the internal plating hub 720 can provide routing flexibility between electrical contacts of the third set. Although not shown in FIG. 7, the internal plating hub 720 in other embodiments can additionally, or alternatively, be coupled to an external contact 750 formed at the second side 705 of the substrate 704. In these embodiments, the internal plating hub 720 of the central hub routing region 715 and one or more electrical contacts at the first side 703 of the substrate 704 can couple the semiconductor device 760 to the external contact 750 formed at the second side 705 of the substrate 704.

The assembly 700 further includes an encapsulant 740. The encapsulant 740 can be formed of a molding compound, such as an epoxy molding compound (EMC), a silicone molding compound, a polyurethane molding compound, a thermoplastic molding compound, or another suitable material. In the illustrated embodiment, the encapsulant 740 surrounds and encapsulates the semiconductor device 760, the inductor 728, and the capacitor 732 that are disposed atop the first side 703 of the substrate 704.

In addition, as shown in FIG. 7, the encapsulant 740 can be used to fill in apertures (e.g., the apertures 524 of FIG. 5C) formed in the substrate 704 and thereby form separators 734 within the substrate 704. For example, the substrate 704 can be provided with apertures formed within the substrate 704 that are devoid of a filler material. Continuing with this example, after the semiconductor device 760, the inductor 728, and/or the capacitor 732 are stacked atop the substrate 704 and coupled to interconnects formed within the substrate 704, the encapsulant 740 can be applied over the semiconductor device 760, the inductor 728, and/or the capacitor 732 such that the encapsulant 740 (a) encapsulates the semiconductor device 760, the inductor 728, and/or the capacitor 732; and (b) fills in the apertures in the substrate 704 to form the separators 734. Alternatively, the substrate 704 can be provided with apertures already filled with (e.g., plugs) of insulating material that serve as separators. Continuing with this example, the semiconductor device 760, the inductor 728, and/or the capacitor 732 can then be stacked atop the substrate 704, and the encapsulant 740 can be applied over the semiconductor device 760, the inductor 728, and/or the capacitor 732 to cover the semiconductor device 760, the inductor 728, and/or the capacitor 732. In either configuration, the separators (e.g., the separators 734) can be configured to separate (e.g., electrically isolate) the internal plating hub 720 from other interconnect structures formed within the substrate 704, and/or two or more interconnect structures formed within the substrate 704 from one another.

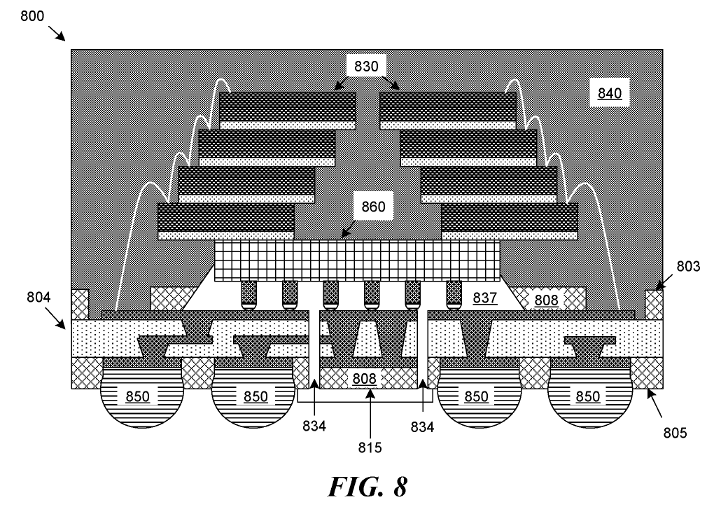

FIG. 8 is a simplified schematic cross-sectional view of still another semiconductor device assembly 800 (“the assembly 800”) configured in accordance with various embodiments of the present technology. As shown, the assembly 800 includes a substrate 804 with an internal plating hub 820. The substrate 804 can be an example of the substrate 104 of FIG. 1, the substrate 204 of FIG. 2, the substrate 304 of FIG. 3, the substrate 404 of FIGS. 4A-4C, the substrate 504 of FIGS. 5A-5C, the substrate 604 of FIG. 6, the substrate 704 of FIG. 7, or other substrates configured in accordance with various embodiments of the present technology. Thus, similar reference numbers are used across FIGS. 1-8 to denote identical or at least generally similar components, and a detailed discussion of such components is largely omitted here for the sake of brevity in light of the detailed discussion provided above with reference to FIGS. 1-7.

The substrate 804 is at least partially formed of a dielectric material 808 having a plurality of interconnect structures (e.g., traces, vias, planes, plating lines, the internal plating hub 820) formed therein. The substrate 804 further includes a first side 803 and a second side 805 opposite the first side 803. The plurality of interconnect structures can extend between the first side 803 and the second side 805. As shown, the internal plating hub 820 is arranged in a central hub routing region 815 of the substrate 804 and can provide routing flexibility, as described in greater detail above with reference to FIG. 7. In some embodiments, the substrate 804 can be a package substrate and/or a printed circuit board.

In the illustrated embodiment, the assembly 700 further includes a semiconductor device 860 and a plurality of semiconductor devices 830 that are (a) stacked atop the substrate 804 on the first side 803 of the substrate 804 and (b) coupled to corresponding external contacts 850 formed at the second side 805 of the substrate 804 via the interconnects within the substrate 804. Indeed, the assembly 800 is generally similar to the assemblies 600 and 700 of FIGS. 6 and 7, respectively, except that (a) the assembly 800 omits an inductor and a capacitor stacked atop the substrate 804 (in contrast with the assembly 700 of FIG. 7) and (b) the plurality of semiconductor devices 830 are stacked atop the semiconductor device 860 as opposed to directly on the first side 803 of the substrate 804 (in contrast with the assembly 600 of FIG. 6).

The semiconductor device 860 can be attached to the first side 803 of the substrate 804 using any suitable technique. For example, the semiconductor device 860 can be attached to the first side 803 of the substrate 804 using a direct chip attach (DCA) technique. In contrast with the assembly 700 of FIG. 7, the semiconductor device 860 of FIG. 8 can be attached to the first side 803 of the substrate 804 using an underfill material 837 (e.g., an epoxy resin, an acrylic, a polyimide, or a silicone). As shown in FIG. 8, the underfill material 837 can (a) fill in gaps between the semiconductor device 860 of the substrate 804 and (b) fill in apertures (e.g., the apertures 524 of FIG. 5C) formed in the substrate 804 and thereby form separators 834 within the substrate 804. For example, the substrate 804 can be provided with apertures formed within the substrate 804 that are devoid of a filler material. Continuing with this example, during the process of attaching the semiconductor device 860 to the first side 803 of the substrate 804, the underfill material 837 can be applied beneath the semiconductor device 860 such that the underfill material 837 (a) fills in gaps between the semiconductor device 860 and the substrate 804, (b) protects electrical connections extending between the semiconductor device 860 and corresponding interconnects formed within the substrate 804, and/or (c) fills in the apertures in the substrate 804 to form the separators 834. Alternatively, the substrate 804 can be provided with apertures already filled with (e.g., plugs) of insulating material that serve as separators. Continuing with this example, the semiconductor device 860 can then be stacked atop the substrate 804, and the underfill material 837 can be applied beneath the semiconductor device 860 to (a) fill in gaps between the semiconductor device 860 and the substrate 804 and/or (b) protect electrical connections extending between the semiconductor device 860 and corresponding interconnects formed within the substrate 804. In either configuration, the separators (e.g., the separators 834) can be configured to separate (e.g., electrically isolate) the internal plating hub 820 from other interconnect structures formed within the substrate 804, and/or two or more interconnect structures formed within the substrate 804 from one another.

The assembly 800 further includes an encapsulant 840. The encapsulant 840 can be formed of a molding compound, such as an epoxy molding compound (EMC), a silicone molding compound, a polyurethane molding compound, a thermoplastic molding compound, or another suitable material. In the illustrated embodiment, the encapsulant 840 surrounds and encapsulates the semiconductor device 860 and the plurality of semiconductor devices 830 that are disposed atop the first side 803 of the substrate 804.

In accordance with one aspect of the present disclosure, the semiconductor devices 630, 760, 830, and/or 860 illustrated in the assemblies 600, 700, and/or 800 of FIGS. 6-8, respectively, could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies 630, 760, 830, and/or 860 illustrated in the assemblies 600, 700, and/or 800 of FIGS. 6-8, respectively, could be logic dies (e.g., controller dies, processor dies, etc.), or a mix of logic and memory dies (e.g., a memory controller die and a memory die controlled thereby).

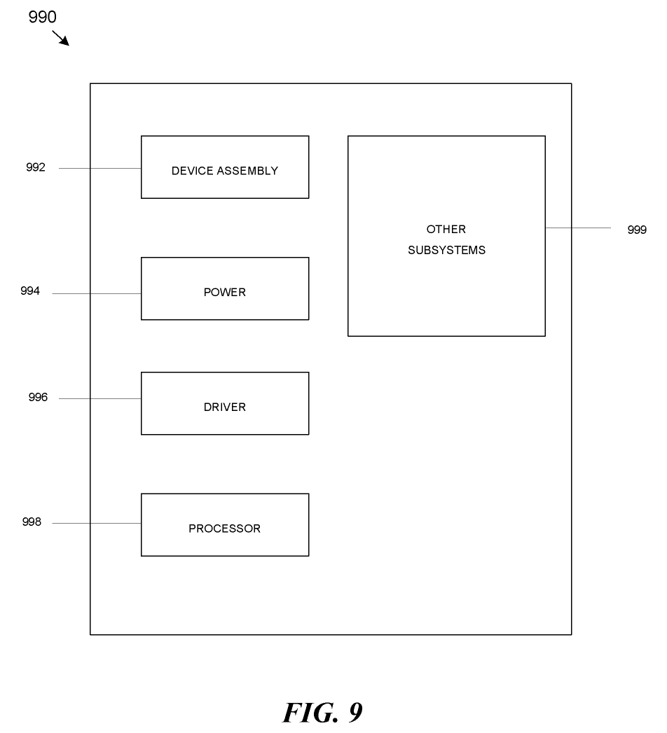

Any one of the substrates, semiconductor devices, and semiconductor device assemblies described above with reference to FIGS. 1-8 can be incorporated into any of a myriad of larger and/or more complex systems, a representative example of which is system 990 shown schematically in FIG. 9. The system 990 can include a semiconductor device assembly (e.g., or a discrete semiconductor device) 992, a power source 994, a driver 996, a processor 998, and/or other subsystems or components 999. The semiconductor device assembly 992 can include features generally similar to those of the semiconductor devices described above with reference to FIGS. 1-8. The resulting system 990 can perform any of a wide variety of functions, such as memory storage, data processing, and/or other suitable functions. Accordingly, representative systems 990 can include, without limitation, hand-held devices (e.g., mobile phones, tablets, digital readers, and digital audio players), computers, vehicles, appliances and other products. Components of the system 990 may be housed in a single unit or distributed over multiple, interconnected units (e.g., through a communications network). The components of the system 990 can also include remote devices and any of a wide variety of computer readable media.

FIG. 10 is a flow chart illustrating a method 1000 of making a substrate and/or a corresponding semiconductor device assembly in accordance with various embodiments of the present technology. The method 1400 includes providing, at block 1010, a substrate having plating lines connected to an internal plating hub. The plating lines and the internal plating hub can both belong to a unified electrical network embedded within the substrate. The substrate can further comprise a dielectric material with openings. Block 1010 of the method 1000 can result in substrates similar to those shown and described in detail above with reference to FIGS. 3-5A.

At block 1020, the method 1000 continues by plating the plating lines using the internal plating hub. Plating the plating lines can include exposing portions of the plating lines, the internal plating hub, and/or other interconnect structures (e.g., traces, pads, vias, planes, lines, etc.) formed within the substrate and/or of the unified electrical network, to a solution (e.g., a metal alloy) comprising metal ions. The portions of the plating lines, the internal plating hub, and/or other interconnect structures can include portions positioned and exposed within the openings in the dielectric material. Plating the plating lines can include supplying a voltage to the solution such that the metal ions are drawn to the internal plating hub through the openings in the substrate and/or through the exposed portions of the plating lines, the internal plating hub, and/or other interconnect structures. Plating the plating lines can further include electrically plating interconnects of the unified electrical network that are coupled to the plating lines and the internal plating hub, by transferring metal ions, for example, from the internal plating hub to the plating lines, and from the plating lines to the interconnects. Block 1020 of the method 1000 can result in substrates similar to those shown and described in detail above with reference to FIGS. 4B and 5B.

In some embodiments, the substrates comprise inner layers. The inner layers can have interconnect structures that form parts of the unified electrical network. These interconnect structures can include one or more vias that vertically connect two or more other interconnectors structure to one another despite each of the two or more other interconnect structures being positioned in different layers of the substrate. Additionally, or alternatively, the internal plating hub can include one or more vias. As a specific example, the internal plating hub can include two or more ground planes that are each positioned at different layers within the substrate, and the internal plating hub can further include one or more vias that vertically connect the two of more ground planes to one another. Plating the plating lines can there include plating the two or more other interconnect structures and/or the two or more ground planes using the one or more vias, such as by transferring metal ions from one of the two or more other interconnect structures/ground planes to the other of the two or more other interconnect structures/ground planes. In this manner, plating the plating lines can include plating electrical features (e.g., interconnect structures) of the unified electrical network that are positioned at inner layers of the substrate.

In some embodiments, plating the plating lines can include developing a protective mask (e.g., a gold (Au) mask) atop the substrate, the protective mask including a plating pattern formed therein. Plating the plating lines can further include (a) electrically plating (e.g., using a Ni/Au plating solution) an exposed portion of the unified electrical network through the plating pattern of the protective mask, and (b) thereafter stripping away the protective mask.

At block 1030, the method 1000 continues by severing connections between the plating lines and the internal plating hub. Severing the connections can include creating one or more apertures in the substrate. In some embodiments, the aperture(s) can be formed using a laser or laser drill (e.g., in addition to or in lieu of using a chemical etchant), or through an etching process. The aperture(s) can extend fully through the substrate from a first side of the substrate to a second side of the substrate opposite the first side. In some such embodiments, the aperture(s) can define (e.g., delineate) a central hub routing region of the substrate that includes the internal plating hub. Alternatively, the aperture(s) can extend a sufficient depth into the substrate to sever the connections between the plating lines and the internal plating hub, and without extending fully through the substrate. In some embodiments, severing the connections can include removing at least a portion of a plating layer formed at block 1020 above, such as a portion of the plating layer that shorts (i) two or more of the plating lines together and/or (ii) one or more of the plating lines to the internal plating hub. Block 1030 of the method 1000 can result in substrates similar to those shown and described in detail above with reference to FIGS. 4C and 5C.

At block 1040, the method 1000 optionally continues by filling in the aperture(s) formed at block 1030 above with an insulating material. The insulating material can comprise a solder resist, an encapsulant/molding compound, an underfill material, or another suitable material. Filling in the aperture(s) can include filling in the apertures with the insulting material (e.g., a solder resist) when manufacturing the substrate. Alternatively, filling in the aperture(s) can include dilling in the apertures with the insulating material (e.g., an encapsulant, an underfill material) when incorporating the substrate into a semiconductor device assembly, such as when or after attached semiconductor devices to a side (e.g., a first side, a top side) of the substrate. As discussed in detail above, the insulating material can separate (e.g., electrically isolate) one or more plating lines from the internal plating hub, and/or two or more plating lines from one another. Additionally, or alternatively, the insulating material can cover portions of the substrate from being exposed to air, thereby reducing the risk of oxidation and/or corrosion. Block 1040 of the method 1400 can result in substrates similar to those shown and described above with reference to FIGS. 1,2, and 5-8.

In some embodiments, the method 1000 can include additional steps than shown in the flow diagram illustrated in FIG. 10. For example, the method 1000 can include stacking one or more semiconductor devices and/or other components (e.g., one or more inductors, one or more capacitors) atop the substrate; coupling, such as using wire bonds and/or other electrical contacts, the semiconductor device(s) to (i) interconnects formed within the substrate and/or (ii) to external contacts formed at a side of the substrate opposite the semiconductor device(s); and/or applying an encapsulant about the semiconductor device(s). Stacking the one or more semiconductor devices atop the substrate can include disposing an underfill material beneath the semiconductor device(s), and between the semiconductor device(s) and the substrate. Such additional steps of the method 1000 can result in semiconductor device assemblies similar to those shown and described above with reference to FIGS. 6-8.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Thus, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.” Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A substrate, comprising:
a dielectric material;
a plated electrical network formed within the dielectric material, the plated electrical network including:
an internal plating hub embedded at least partially within the dielectric material, the internal plating hub spanning multiple layers of the substrate that are positioned between (i) a first side of the substrate and (ii) a second side of the substrate opposite the first side, and
a plurality of plating lines; and
one or more separators positioned between one or more plating lines of the plurality of plating lines and the internal plating hub.

2. The substrate of claim 1, wherein the internal plating hub comprises one or more ground planes.

3. The substrate of claim 2, wherein the one or more ground planes include two or more ground planes, and wherein the internal plating hub further comprises one or more vias electrically connecting the two or more ground planes.

4. The substrate of claim 1, wherein the separators comprise an insulating material extending (a) from one of the first side or the second side of the substrate toward (b) another of the first side or the second side.

5. The substrate of claim 4, wherein the insulating material comprises at least one of a solder resist, a molding compound, or an underfill material.

6. The substrate of claim 1, wherein the separators cover portions of the one or more plating lines and portions of the internal plating hub such that the portions of the one or more plating lines and the portions of the internal plating hub are not exposed to air.

7. The substrate of claim 1, further comprising one or more openings formed in the dielectric material, wherein portions of the plated electrical network are positioned within the one or more openings, and wherein the substrate further comprises a plating layer disposed within the one or more openings and over the positions of the plated electrical network.

8. The substrate of claim 1, wherein the plurality of plating lines include a first plating line arranged at a first layer within the substrate, a second plating line arranged at a second layer within the substrate that is closer to the second side of the substrate than the first layer, and a third plating line arranged at a third layer that is positioned between the first layer and the second layer.

9. The substrate of claim 1, wherein the one or more separators include one or more unfilled apertures formed in the substrate.

10. The substrate of claim 1, wherein the one or more separators include (a) a first separator positioned on a first side of the internal plating hub, and (b) a second separator positioned on a second side of the internal plating hub opposite the first side of the internal plating hub.

11. A semiconductor device assembly, comprising:
a substrate including a first side and a second side opposite the first side, the substrate further including:
a dielectric material,
an electrical network formed within the dielectric material, the electrical network including:
an internal plating hub comprising one or more ground planes; and
a plurality of plating lines, and
one or more separators positioned (a) between the internal plating hub and one or more plating lines of the plurality of plating lines, and (b) such that the one or more separators electrically isolate the internal plating hub from the one or more plating lines; and
at least one semiconductor device stacked on the first side of the substrate.

12. The semiconductor device assembly of claim 11, wherein the one or more ground planes include two or more ground planes, and wherein the internal plating hub further comprises one or more vias electrically connecting the two or more ground planes.

13. The semiconductor device assembly of claim 11, wherein:
the one or more separators include (a) a first separator positioned on a first side of the internal plating hub, and (b) a second separator positioned on a second side of the internal plating hub opposite the first side of the internal plating hub;
the first and second separators delineate a central hub routing region of the substrate; and
the central hub routing region includes the internal plating hub.

14. The semiconductor device assembly of claim 11, wherein the at least one semiconductor device is electrically connected to the internal plating hub at the first side of the substrate.

15. The semiconductor device assembly of claim 11, further comprising an underfill material (a) positioned between the at least one semiconductor device and the first side of the substrate, and (b) forming at least part of the one or more separators.

16. The semiconductor device assembly of claim 11, further comprising a molding compound (a) encapsulating the at least one semiconductor device and (b) forming at least part of the one or more separators.

17. The semiconductor device assembly of claim 11, further comprising an external contact formed at the second side of the substrate, wherein the electrical network further includes one or more interconnect structures electrically connecting the at least one semiconductor device to the external contact, and wherein the one or more interconnect structures include a plating line of the plurality of plating lines.

18. A method of making a substrate, the method comprising:
providing a substrate having a unified electrical network embedded within a dielectric material, the unified electrical network including plating lines connected to an internal plating hub;
plating the unified electrical network using the plating lines and the internal plating hub; and
severing connections between the plating lines and the internal plating hub.

19. The method of claim 18, wherein severing the connections between the plating lines and the internal plating hub comprises creating one or more apertures in the substrate using a laser.

20. The method of claim 19, further comprising filling the one or more apertures with an insulating material.
